(19) United States
(12) Patent Application Publication
(10) Pub. No.: US 2013/0271101 A1
(43) Pub. Date: Oct. 17, 2013

(54) POWER CONVERSION SYSTEM EMPLOYING A TRI-STATE INTERFACE CIRCUIT AND METHOD OF OPERATION THEREOF

(71) Applicant: Ivan D. Nanov, Plano, TX (US)

(72) Inventor: Ivan D. Nanov, Plano, TX (US)

(73) Assignee: General Electric, a New York corporation, Schenectady, NY (US)

(21) Appl. No.: 13/447,730

(22) Filed: Apr. 16, 2012

(51) Int. Cl. G05F 1/00; H03K 17/00

(52) U.S. Cl. 323/282; 327/365

(57) ABSTRACT

A power converter system includes a controller that provides first and second bistate control signals having mutually exclusive true logic states. Also included is a tri-state interface circuit having a switching stage that generates a tri-state output, wherein true and false logic states correspond to the mutually exclusive true logic states and a high impedance state corresponds to concurrent false logic states of the first and second bistate control signals. The tri-state interface circuit also has a level setting stage that controls a voltage level of the tri-state output during the high impedance state. The power converter system further includes a driver that converts the voltage level of the tri-state output to power stage control signals and a power stage that converts an input voltage to an output voltage based on the power stage control signals. A method of operating a tri-state interface circuit is also provided.

### TECHNICAL FIELD

This application is directed, in general, to power conversion and, more specifically, to a tri-state interface circuit, a method of operating a tri-state interface circuit and a power conversion system employing a tri-state interface circuit.

### BACKGROUND

Switching regulators are commonly used in DC to DC power conversion since they offer higher operating efficiency than linear regulators. In their most basic form, they typically consist of an inductor, a capacitor, a diode and a switch that alternately switches the inductor between charging and discharging states. These basic elements can be arranged to form various power converter architectures, which include step-down (buck), step-up (boost) and inverting (buck-boost) configurations, for example. In low-voltage high-current applications, the diode may be replaced by another switch in a synchronous rectification arrangement that improves operating efficiency. This synchronous rectification architecture requires two control signals separated by a “dead time” that prevents both switches from being activated simultaneously. Separation of the control signals also allows control of the operating mode of the converter (i.e., continuous or discontinuous inductor current modes). Improvements in present operating arrangements would prove beneficial to the art.

### SUMMARY

Embodiments of the present disclosure provide a tri-state interface circuit, a method of operating a tri-state interface circuit and a power conversion system employing a tri-state interface circuit.

In one embodiment, the tri-state interface circuit includes first and second bistate control signals having mutually exclusive true logic states. The tri-state interface circuit also includes a switching stage configured to generate a tri-state output, wherein true and false logic states correspond to the mutually exclusive true logic states and a high impedance state corresponds to concurrent false logic states of the first and second bistate control signals.

In another aspect, the method of operating a tri-state interface circuit includes providing first and second bistate control signals having mutually exclusive true logic states and generating a tri-state output, wherein true and false logic states correspond to the mutually exclusive true logic states and a high impedance state corresponds to concurrent false logic states of the first and second bistate control signals.

In yet another aspect, the power converter system includes a controller that provides first and second bistate control signals having mutually exclusive true logic states. The power converter system also includes a tri-state interface circuit having a switching stage that generates a tri-state output, wherein true and false logic states correspond to the mutually exclusive true logic states and a high impedance state corresponds to concurrent false logic states of the first and second bistate control signals. The tri-state interface circuit also has a level setting stage that controls a voltage level of the tri-state output during the high impedance state. The power converter system further includes a driver that converts the voltage level of the tri-state output to power stage control signals and a power stage that converts an input voltage to an output voltage based on the power stage control signals.

The foregoing has outlined preferred and alternative features of the present disclosure so that those skilled in the art may better understand the detailed description of the disclosure that follows. Additional features of the disclosure will be described hereinafter that form the subject of the claims of the disclosure. Those skilled in the art will appreciate that they can readily use the disclosed conception and specific embodiment as a basis for designing or modifying other structures for carrying out the same purposes of the present disclosure.

### BRIEF DESCRIPTION

Reference is now made to the following descriptions taken in conjunction with the accompanying drawings, in which:

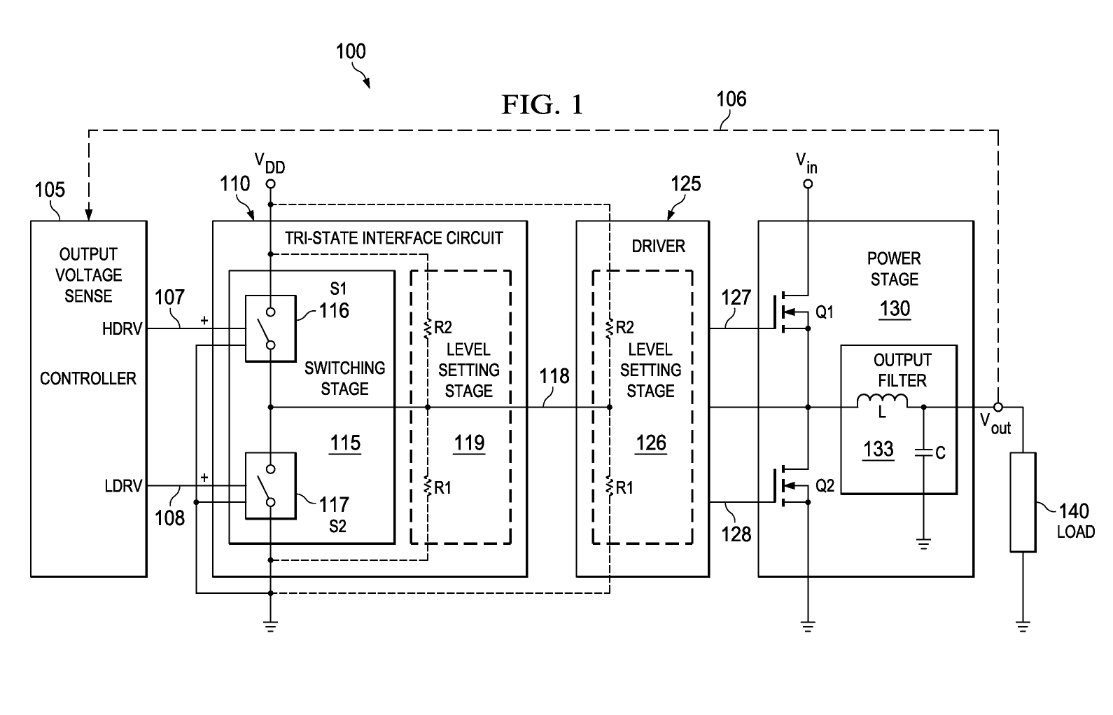

FIG. 1 illustrates a block diagram of an embodiment of a power conversion system constructed according to the principles of the present disclosure;

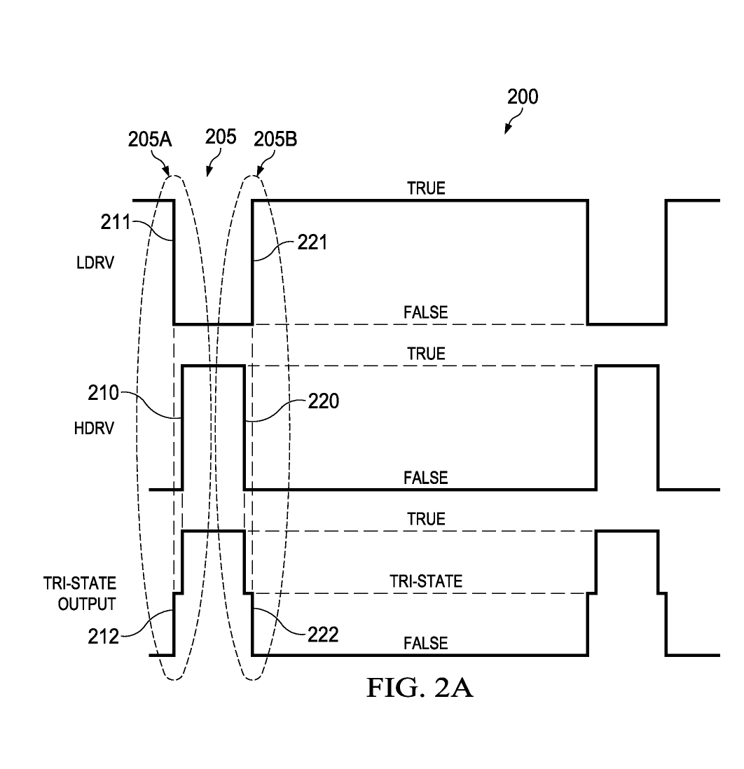

FIGS. 2A, 2B, 2C and 2D illustrate waveforms corresponding to the simplified block diagram of the tri-state interface circuit of FIG. 1;

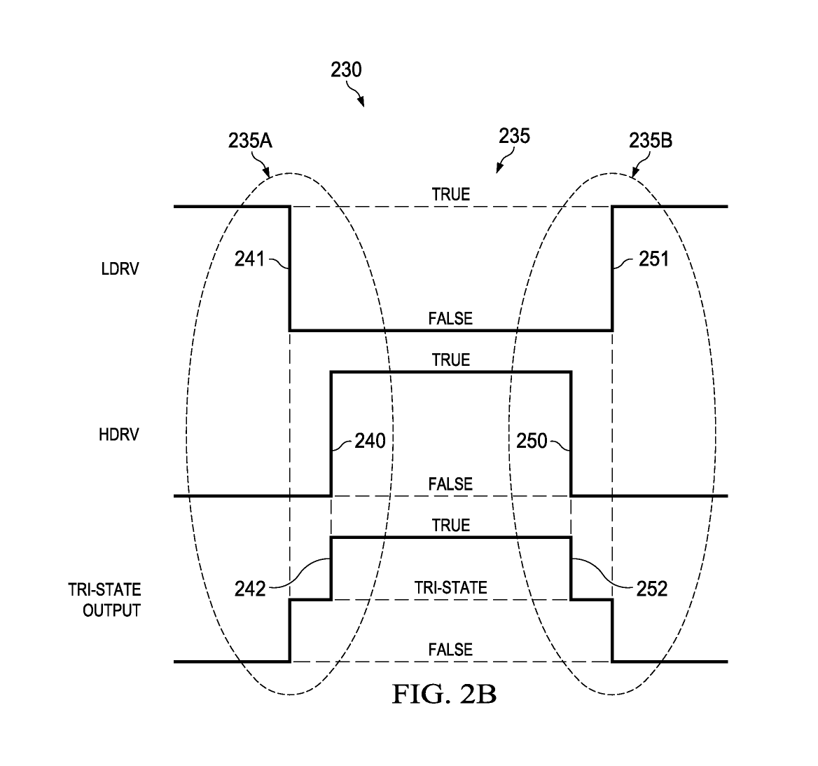

FIG. 3 illustrates another embodiment of a tri-state interface circuit employing a field effect transistor and constructed according to the principles of the present disclosure;

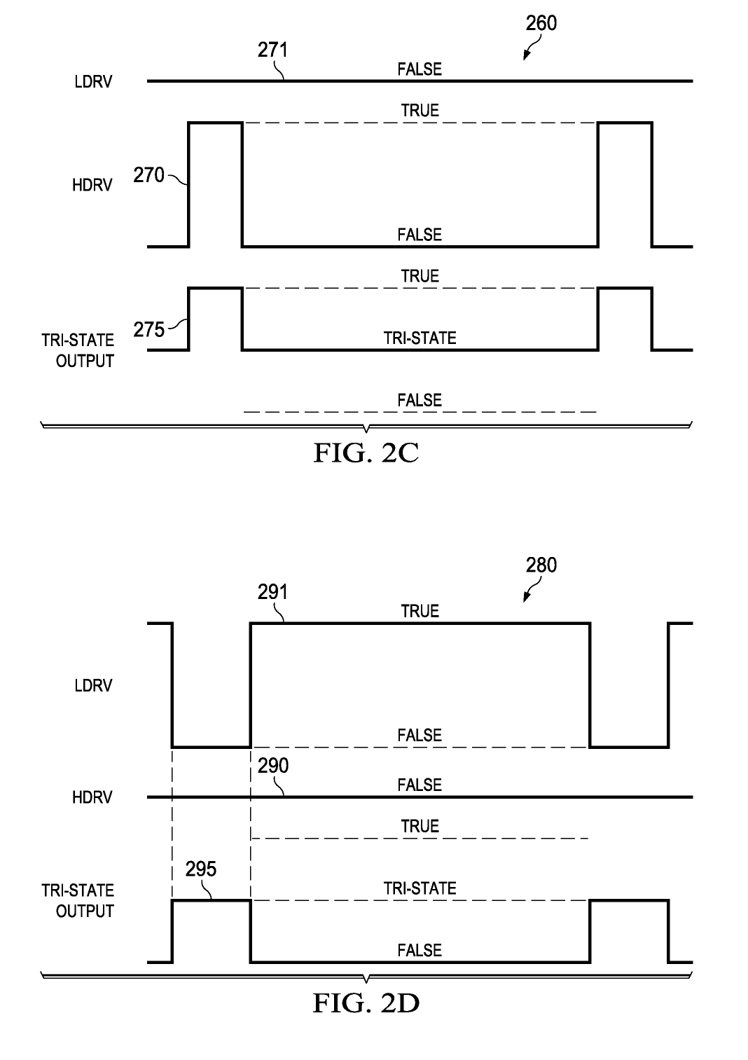

FIG. 4 illustrates an alternate embodiment of a tri-state interface circuit constructed according to the principles of the present disclosure;

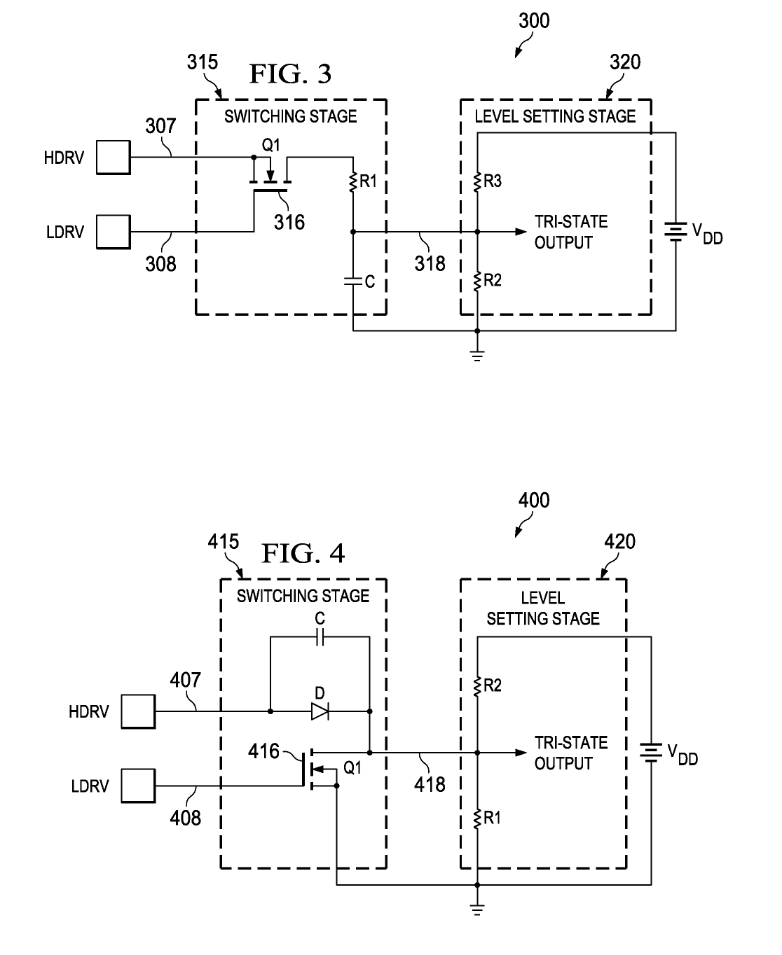

FIG. 5 illustrates yet another embodiment of a tri-state interface circuit constructed according to the principles of the present disclosure;

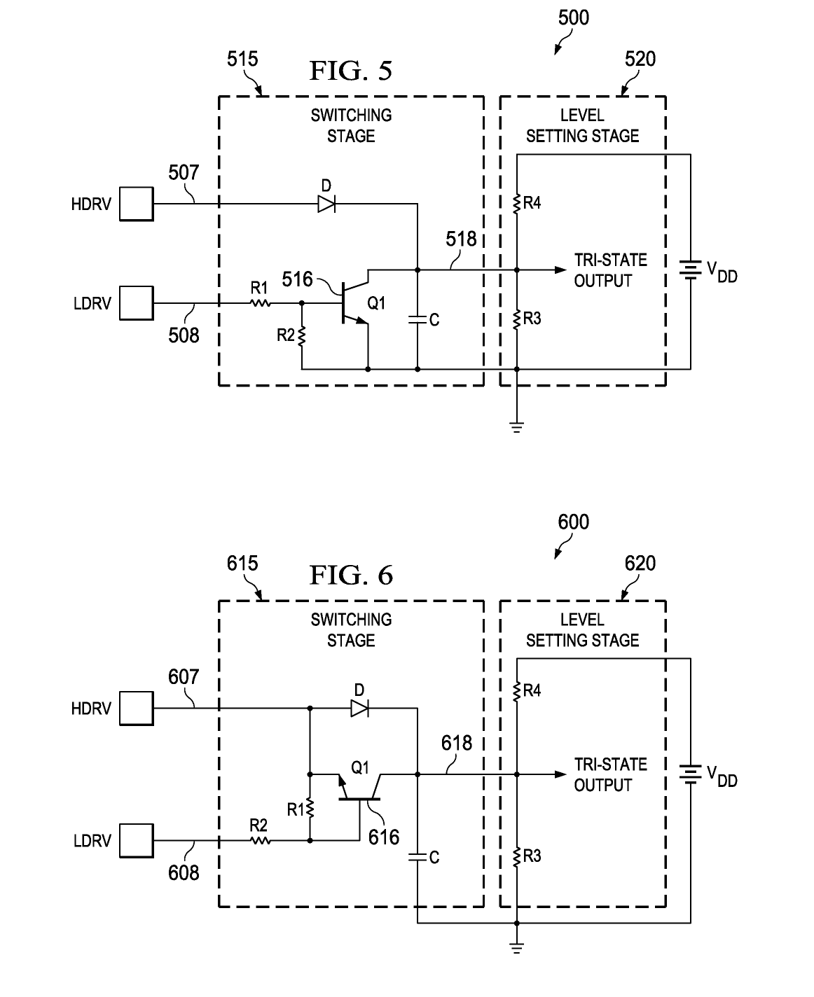

FIG. 6 illustrates a further embodiment of a tri-state interface circuit constructed according to the principles of the present disclosure; and

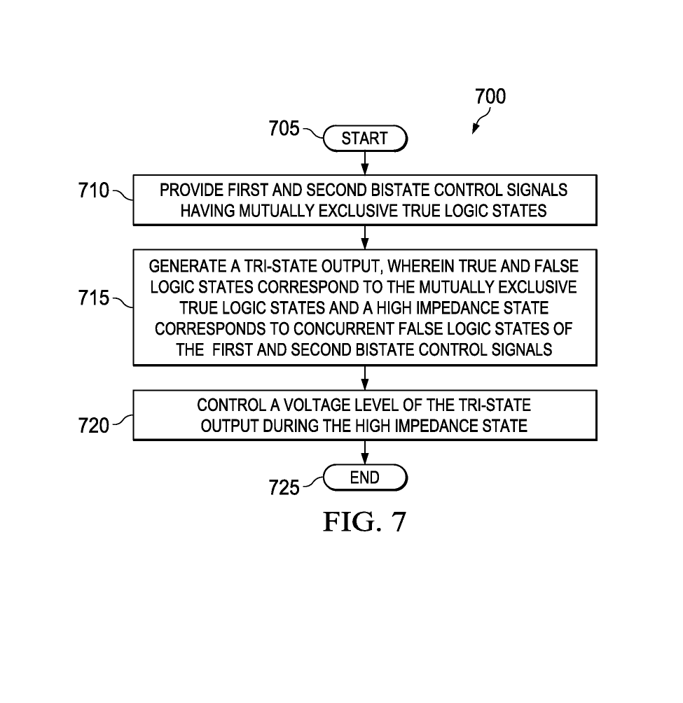

FIG. 7 illustrates an embodiment of a flow diagram of a method of operating a tri-state interface circuit carried out according to the principles of the present disclosure.

### DETAILED DESCRIPTION

The output voltage of a switching regulator converter may be controlled by adjusting the duration of the charging state of a control switch. At the beginning of each cycle, the control switch is activated for a time determined by a control circuit. When the control switch is deactivated, a diode may provide a path for an inductor current to flow. The diode conducts until the inductor current reaches zero and all the energy stored in the inductor is depleted. An operational mode in which the inductor current becomes zero for a portion of the switching cycle is known as a discontinuous inductor current mode.

An important aspect of synchronous converters is that they may start-up in a “diode emulation” mode when the output is pre-biased thereby not allowing a negative output current flow, and later transition to synchronous operation when the output is higher than the pre-biased output voltage. To allow this functionality, the conduction time of a synchronous switch is additionally controlled, wherein its maximum value is equal to the switching cycle period minus the sum of two dead time intervals and a conduction time of the control switch.

Demand for higher power density has driven integration of drivers of the control and synchronous switches either into a control circuit (e.g., a pulse-width modulation (PWM) controller), or into the same silicon with the power converter switches. Inside synchronous PWM controllers with integrated drivers, a control switch driver and a synchronous switch driver may be controlled individually. Control for power stages that employ control and synchronous switches along with their drivers in either discrete or integrated configurations, may be supplied through a single control input that provides a control signal (e.g., a PWM signal) from which control signals for the control and synchronous switches are reconstructed.

In an example of a driver integrated with power stage switches, or a discrete driver and discrete control and synchronous switches, the control switch is conducting and the synchronous switch is not conducting if the control signal at the driver's control input is in a TRUE logic state. Correspondingly, if the driver's control signal is in a FALSE logic state, the control switch is not conducting and the synchronous switch is conducting. If the source of the control signal is in a high impedance state for a predetermined period of time, both the control and the synchronous switches will not be conducting (i.e., substantially electrically open). This high impedance state may be used to turn off the converter, or to configure it to operate in a diode emulation mode when the control signal toggles between the TRUE logic state and the high impedance state. Consequently, a tri-state control signal is defined as one having a TRUE logic state, a FALSE logic state and a high impedance state.

The need for a tri-state control signal to control a power stage with a build-in driver, similar to the one mentioned above, seriously limits the use of PWM controllers with build-in drivers. If a charging state control signal (i.e., a signal that drives a control switch) is used to control the power stage's driver, the power stage would deliver less functionality and performance than desired. The output of a controller's build-in driver, which has no tri-state capability, will not be able to force the power stage into a diode emulation mode or to shut it down. As a result, during a pre-bias start-up, the converter may sink current or at light loads multi-phase converters may not be able to shut down phases to improve efficiency.

Generally, embodiments of the present disclosure provide a capability to interface a device providing two bistate control signals to a device requiring a tri-state signal. In one application, embodiments of the present disclosure provide a capability to interface a controller with build-in drivers to a tri-state PWM input of an external driver or a power stage with a build-in driver and maintain the ability of the power train to work in a diode emulation mode as well as other features controlled via a tri-state condition at the driver's input. This capability is essential during a pre-bias start-up condition to prevent a negative output current and to improve conversion efficiency while operating under light load conditions.

FIG. 1 illustrates a block diagram of an embodiment of a power conversion system, generally designated 100, constructed according to the principles of the present disclosure. The power conversion system 100 includes a controller 105, a tri-state interface circuit 110, a driver 125 and a power stage 130 connected to a load 140.

The controller 105 employs an output voltage sense connection 106 that allows closed loop control of an output voltage Vout across the load 140. The controller 105 provides first and second bistate control signals HDRV 107, LDRV 108 having mutually exclusive TRUE logic states and concurrent FALSE logic states. Therefore, their TRUE logic states do not overlap in time while their FALSE logic states overlap in time.

The tri-state interface circuit 110 includes a switching stage 115 that generates a tri-state output 118 controlled by the first and second bistate control signals HDRV 107, LDRV 108. The tri-state output 118 provides TRUE and FALSE logic states that correspond to the mutually exclusive TRUE logic states and a high impedance state that corresponds to concurrent FALSE logic states of the first and second bistate control signals HDRV 107, LDRV 108.

In the illustrated embodiment, the switching stage 115 illustrates a generalized diagram that employs first and second switches 116, 117 (i.e., separate switching devices) to combine the two bistate control signals HDRV 107, LDRV 108 into a tri-state control signal on the tri-state output 118. When the first bistate control signal HDRV 107 is in a TRUE logic state, only the first switch 116 is closed and the tri-state output 118 is in a TRUE logic state. When the second bistate control signal LDRV 108 is in a TRUE logic state, only the second switch 117 is closed and the tri-state output 118 is in a FALSE logic state. When the first and second bistate control signals HDRV 107, LDRV 108 are in concurrent FALSE logic states, both first and second switches 116, 117 are open, and the tri-state output 118 is in the high impedance state for the interval of concurrent FALSE logic states.

In the illustrated embodiment, a level setting stage is employed to control a voltage level of the tri-state output 118 during its high impedance state. An internal level setting stage 119 that is integral with the tri-state interface circuit 110, may be employed. Alternately, an external level setting stage 126 that is integral with the driver 125 may be employed. The level setting stage may generally be a network that provides a voltage level or a resistive divider R1 and R2, as shown.

The driver 125 converts the condition of the tri-state output 118 to first and second power stage control signals 127, 128. The power stage 130 includes first and second transistor switches Q1, Q2 that convert an input voltage Vin to the output voltage Vout based on the power stage control signals 127, 128. Additionally, the power stage 130 includes an output filter 133 employing an inductor L and a capacitor C that provide smoothing of the output voltage Vout for the load 140. Examples of waveforms for the bistate control signals HDRV 107, LDRV 108 and the tri-state output 118 are discussed with respect to FIGS. 2A, 2B, 2C and 2D.

FIGS. 2A, 2B, 2C and 2D illustrate waveforms, generally designated 200, 230, 260, 280 corresponding to the simplified block diagram of the tri-state interface circuit 110 of FIG. 1. The waveforms 200 show the tri-state interface circuit 110 signals during synchronous operation mode, and the waveforms 230 are expanded representations of these waveforms for concurrent FALSE logic states of the first and second bistate control signals HDRV 107, LDRV 108. The waveforms 260 show an example of the tri-state interface circuit 110 signals during operation in diode emulation mode. The waveforms 280 show an example of the tri-state interface circuit 110 signals during operation in a load current sinking mode.

The waveforms 200 generally show mutually exclusive TRUE logic states for the first and second bistate control signals HDRV 107, LDRV 108. The waveforms 200 also include a waveform portion 205 having transition zones 205A, 205B that include concurrent FALSE logic states of the bistate control signals HDRV 107, LDRV 108. The transition zones 205A, 205B show leading and trailing HDRV waveforms 210, 220, leading and trailing LDRV waveforms 211, 221 and leading and trailing tri-state output waveforms 212, 222. When HDRV is in its TRUE logic state (e.g., about the driver's supply voltage), the tri-state output is also in its TRUE logic state, and when LDRV is in its TRUE logic state, the tri-state output is in its FALSE logic state (e.g., about ground potential)

The waveforms 230 include a corresponding waveform portion 235 showing expanded transition zones 235A, 235B corresponding to the transition zones 205A, 205B, respectively. Here, leading and trailing HDRV waveforms 240, 250 correspond to the HDRV waveforms 210, 220, leading and trailing LDRV waveforms 241, 251 correspond to the LDRV waveforms 211, 221 and leading and trailing tri-state output waveforms 242, 252 correspond to the leading and trailing tri-state output waveforms 212, 222.

As may be seen in either of the expanded view transition zones 235A, 235B, the tri-state output may assume a voltage that is within a range between FALSE and TRUE logic levels as determined by a level setting stage, when employed. This occurs when the HDRV and LDRV waveforms are both in a FALSE logic state (e.g., about ground potential) and the tri-state output asserts its high impedance state after a delay associated with signal propagation time. There are delays when the tri-state output transitions from the FALSE logic state to the high impedance state and from the high impedance state to the TRUE logic state, as well as when these transitions are reversed. These delays may not be equal. The propagation delays are not shown in the idealized waveforms 200, 230, 260 and 280.

The waveforms 260 include an example of an HDRV waveform 270, an LDRV waveform 271 and a corresponding tri-state output waveform 275 of the tri-state interface circuit 110 for a mode of operation in which a synchronous converter operates in a diode emulation mode. For this case, the LDRV waveform 271 is maintained in a FALSE logic state, and the tri-state output waveform 275 follows the HDRV waveform 270 for the portion of a switching cycle where the HDRV waveform 270 is in a TRUE logic state. Otherwise, the tri-state output waveform 275 remains in a tri-state voltage window (corresponding to a level setting stage) until the state of the input signals change.

The waveforms 280 include an example of an HDRV waveform 290, an LDRV waveform 291 and a corresponding tri-state output waveform 295 of the tri-state interface circuit 110 for a mode of operation in which a synchronous converter is forced to sink current from a load. For this case, the HDRV waveform 290 is maintained in a FALSE logic state, and the tri-state output waveform 295 is in a FALSE logic state when the LDRV waveform 291 is in a TRUE logic state. Otherwise, the tri-state output waveform 295 remains in a tri-state voltage window (corresponding to a level setting stage) until the state of the input signals changes.

FIG. 3 illustrates another embodiment of a tri-state interface circuit, generally designated 300, employing a field effect transistor and constructed according to the principles of the present disclosure. The tri-state interface circuit 300 includes a switching stage 315 and an optional level setting stage 320. The switching stage 315 includes a single N-channel field effect transistor (FET) 316 connected to bistate control signals HDRV 307 and LDRV 308. The source of the FET 316 is connected to the bistate control signal HDRV 307, the gate of the FET 316 is connected to the bistate control signal LDRV 308, and the drain of the FET 316 is connected through a first resistor R1 to provide a tri-state output 318. The switching stage 315 also includes a capacitor C, as shown. The level setting stage 320 includes second and third resistors R2, R3 connected across a voltage supply V_{DD}, as shown.

The single FET 316 serves as both the first and second switches 116, 117 of FIG. 1. The first switch 116 is implemented by the parasitic anti-parallel body diode of the FET 316. The second switch 117 is implemented by the drain to source channel of the FET 316. The first resistor R1 and the capacitor C1 form an optional network that shapes the signal at the tri-state output 318 to resemble output waveforms corresponding to those discussed with respect to FIG. 1 (i.e., FIGS. 2A, 2B, 2C, 2D). The capacitor C1 may be used to match the parasitic drain to source capacitance of the FET 316, wherein the resistor R1 determines a charge exchange rate between the capacitor C1 and parasitic drain to source capacitance of the FET 316.

When the bistate control signal HDRV 307 is in a TRUE logic state, the anti-parallel body diode conducts and the tri-state output 318 is pulled to its TRUE logic state. When the bistate control signal HDRV 307 is in a FALSE logic state, the anti-parallel body diode of the FET 316 is reverse biased, and as long as the bistate control signal LDRV 308 is in a FALSE logic state, the FET 316 does not conduct current thereby placing the tri-state output 318 in a high impedance state. When the bistate control signal LDRV 308 changes to a TRUE logic state, the bistate control signal HDRV 307 is required to be in a FALSE logic state. The TRUE logic state on the gate of the FET 316 activates the FET 316, and the tri-state output 318 is pulled to a FALSE logic state. The second and third resistors R2, R3 set the voltage level of the tri-state output 318 when both the bistate control signals HDRV 307 and LDRV 308 are in FALSE logic states, as before.

FIG. 4 illustrates an alternate embodiment of a tri-state interface circuit, generally designated 400, constructed according to the principles of the present disclosure. The tri-state interface circuit 400 includes a switching stage 415 and an optional level setting stage 420. The switching stage 415 includes a diode D and a capacitor C connected between a bistate control signal HDRV 407 and a tri-state output 418. The switching stage 415 also includes a FET 416 wherein its drain is also connected to the tri-state output 418. The source of the FET 416 is connected to the grounded side of a voltage supply V_{DD}, and the gate of the FET 418 is connected to a bistate control signal LDRV 408. The level setting stage 420 includes first and second resistors R1, R2 connected to the tri-state output 418 and across the voltage supply V_{DD}.

The bistate control signals HDRV 407 and LDRV 408 provide mutually exclusive TRUE and concurrent FALSE logic states, as before. Here, the first switch 116 of FIG. 1 is implemented by the diode D and the second switch 117 is implemented by the FET 416. The capacitor C is optional wherein its function is to match the capacitance across the diode D with the parasitic drain to source capacitance of the FET 416. When these capacitances are matched, the transient swing of the signal on the tri-state output 418 is minimized. The overall operation of the tri-state interface circuit 400 is similar to the operation of the tri-state interface circuit 300 of FIG. 3.

FIG. 5 illustrates yet another embodiment of a tri-state interface circuit, generally designated 500, constructed according to the principles of the present disclosure. The tri-state interface circuit 500 includes a switching stage 515 and an optional level setting stage 520. The switching stage 515 includes a diode D connected between a bistate control signal HDRV 507 and a tri-state output 518. The switching stage 515 also includes a bipolar junction transistor (BJT) 516 wherein its collector is also connected to the tri-state output 518. The emitter of the BJT 516 is connected to the grounded side of a voltage supply V_{DD}, and the base of the BJT 516 is connected to a bistate control signal LDRV 508 through a first resistor R1. The switching stage 515 further includes a second resistor R2 where the first and second resistors R1, R2 form a base resistor divider connected to the BJT 516 and an optional capacitor C connected between the collector and the emitter of the BJT 516. The level setting stage 520 includes third and fourth resistors R3, R4 that are connected to the tri-state output 518 and a grounded side of a voltage supply V_{DD}, as shown.

The bistate control signals HDRV 507 and LDRV 508 provide input control signals, as before. In this embodiment, the first switch 116 of FIG. 1 is implemented by the diode D and the second switch 117 is implemented by the BJT 516. The capacitor C is optional wherein its function is to match the capacitance between emitter and collector terminals of the BJT 516 with the capacitance across the diode D. When these capacitances are matched, the transient swing of the signal on the tri-state output 518 is minimized. The overall operation of the tri-state interface circuit 500 is similar to the operation of the tri-state interface circuit 300 of FIG. 3.

FIG. 6 illustrates a further embodiment of a tri-state interface circuit, generally designated 600, constructed according to the principles of the present disclosure. The tri-state interface circuit 600 includes a switching stage 615 and an optional level setting stage 620. The switching stage 615 includes a diode D connected between a bistate control signal HDRV 607 and a tri-state output 618. The switching stage 615 also includes a bipolar junction transistor (BJT) 616 where the collector of the BJT 616 is also connected to the tri-state output 618. The emitter of the BJT 616 is connected to the bistate control signal HDRV 607 and to the base of the BJT 616 through a first resistor R1, and the base is further connected to a bistate control signal LDRV 608 through a second resistor R2. The switching stage 615 additionally includes a capacitor C connected between the tri-state output 618 and a grounded side of a voltage supply V_{DD}. The level setting stage 620 includes third and fourth resistors R3, R4 connected to the tri-state output 618 and the voltage supply V_{DD}, as shown.

Again, the bistate control signals HDRV 607 and LDRV 608 provide mutually exclusive TRUE logic states and concurrent FALSE logic states. In this embodiment, the first switch 116 of FIG. 1 is implemented by the diode D and the second switch 117 is implemented by the BJT 616. The first and second resistors R1, R2 form a voltage divider driving circuit for the BJT 616. The capacitor C is optional where its function is to match the capacitance between emitter and collector terminals of the BJT 616 with the capacitance across the tri-state output 618. When these capacitances are matched, the transient swing of the signal on the tri-state output 618 is minimized. The overall operation of the tri-state interface circuit 600 is similar to the operation of the tri-state interface circuit 300 of FIG. 3.

FIG. 7 illustrates an embodiment of a flow diagram of a method of operating a tri-state interface circuit, generally designated 700, carried out according to the principles of the present disclosure. The method 700 starts in a step 705, and first and second bistate control signals having mutually exclusive true logic states are provided in a step 710. Then, in a step 715, a tri-state output is generated, wherein true and false logic states correspond to the mutually exclusive true logic states and a high impedance state corresponds to concurrent false logic states of the first and second bistate control signals.

In one embodiment, the tri-state output employs separate switching devices to provide the high impedance state. In another embodiment, the tri-state output employs a single switching device to provide the high impedance state, wherein the single switching device is a field effect transistor.

In the illustrated embodiment, the method 700 further includes an optional step 720, wherein a voltage level of the tri-state output during the high impedance state is controlled. Controlling the voltage level is selected from the group consisting of internally controlling the voltage level and externally controlling the voltage level. In one example, controlling the voltage level is provided by a resistive network. The method 700 ends in a step 725.

While the method disclosed herein has been described and shown with reference to particular steps performed in a particular order, it will be understood that these steps may be combined, subdivided, or reordered to form an equivalent method without departing from the teachings of the present disclosure. Accordingly, unless specifically indicated herein, the order or the grouping of the steps is not a limitation of the present disclosure.

Those skilled in the art to which this application relates will appreciate that other and further additions, deletions, substitutions and modifications may be made to the described embodiments.

1. A tri-state interface circuit, comprising:
first and second bistate control signals having mutually exclusive first polarity logic states; and
a switching stage configured to generate a tri-state output, wherein a first polarity logic state of the tri-state output corresponds to the first polarity logic state of the first bistate control signal, wherein a second polarity logic state of the tri-state output corresponds to the first polarity logic state of the second bistate control signal, wherein a high impedance state of the tri-state output corresponds to concurrent second polarity logic states of the first and second bistate control signals, and wherein the first polarity is the opposite of the second polarity.

2. The circuit as recited in claim 1 wherein the switching stage employs separate switching devices to generate the high impedance state of the tri-state output.

3. The circuit as recited in claim 1 wherein the switching stage employs a single switching device to generate the high impedance state of the tri-state output.

4. The circuit as recited in claim 3 wherein the single switching device is at least one of a field effect transistor, a diode, and a bipolar junction transistor.

5. The circuit as recited in claim 1 further comprising a level setting stage configured to control a voltage level of the high impedance state.

6. A method of operating a tri-state interface circuit, comprising:
providing first and second bistate control signals having mutually exclusive first polarity logic states; and
generating a tri-state output, wherein a first polarity logic state of the tri-state output corresponds to the first polarity logic state of the first bistate control signal, wherein a second polarity logic state of the tri-state output corresponds to the first polarity logic state of the second bistate control signal, wherein a high impedance state of the tri-state output corresponds to concurrent second polarity logic states of the first and second bistate control signals, and wherein the first polarity is the opposite of the second polarity.

7. The method as recited in claim 6 wherein generating the tri-state output employs separate switching devices to provide the high impedance state.

8. The method as recited in claim 6 wherein generating the tri-state output employs a single switching device to provide the high impedance state.

9. The method as recited in claim 8 wherein the single switching device is at least one of a field effect transistor, a diode, and a bipolar junction transistor.

10. The method as recited in claim 6 further comprising controlling a voltage level of the tri-state output during the high impedance state.

11. The method as recited in claim 10 wherein controlling the voltage level is selected from the group consisting of:
internally controlling the voltage level; and
externally controlling the voltage level.

12. The method as recited in claim 10 wherein controlling the voltage level is provided by a resistive network.

13. A power conversion system, comprising:
a controller that provides first and second bistate control signals having mutually exclusive first polarity logic states;
a tri-state interface circuit, including:
a switching stage that generates a tri-state output, wherein a first polarity logic state of the tri-state output corresponds to the first polarity logic state of the first bistate control signal, wherein a second polarity logic state of the tri-state output corresponds to the first polarity logic state of the second bistate control signal, wherein a high impedance state of the tri-state output corresponds to concurrent second polarity logic states of the first and second bistate control signals, and wherein the first polarity is the opposite of the second polarity, and
a level setting stage that controls a voltage level of the tri-state output during the high impedance state; and
a driver that converts the voltage level of the tri-state output to power stage control signals; and
a power stage that converts an input voltage to an output voltage based on the power stage control signals.

14. The system as recited in claim 13 wherein the switching stage employs separate switching devices to generate the high impedance state of the tri-state output.

15. The system as recited in claim 13 wherein the switching stage employs a single switching device to provide the high impedance state of the tri-state output.

16. The system as recited in claim 15 wherein the single switching device is at least one of a field effect transistor, a diode, and a bipolar junction transistor.

17. The system as recited in claim 13 wherein the level setting stage is selected from the group consisting of:
a stage integral with the switching stage; and
a stage external to the switching stage.

18. The system as recited in claim 13 wherein the level setting stage is a resistive divider.

19. The circuit as recited in claim 5 wherein the level setting stage is selected from the group consisting of:
a stage integral with the switching stage; and
a stage external to the switching stage.

20. The circuit as recited in claim 5 wherein the level setting stage is a resistive divider.
